(19) United States
(12) Patent Application Publication
(10) Pub. No.: US 2009/0121245 A1
(43) Pub. Date: May 14, 2009

(54) Optoelectronic Semiconductor Chip

(76) Inventor: Ralph Wirth, Mintraching-Auhof (DE)

Correspondence Address: COHEN, PONTANI, LIEBERMAN & PAVANE LLP, 551 FIFTH AVENUE, SUITE 1210, NEW YORK, NY, 10176, US

(21) Appl. No.: 11/992,843

(22) PCT Filed: Sep. 14, 2006
(86) PCT No.: PCT/DE2006/001615

§ 371 Date: Oct. 31, 2008

(30) Foreign Application Priority Data
Sep. 30, 2005 (DE) 10 2005 047 168.4

(51) Int. Cl. H01L 33/00

(52) U.S. Cl. 257/98; 257/79; 257/E33.055

(57) ABSTRACT

An optoelectronic semiconductor chip is disclosed which emits electromagnetic radiation from its front side (7) during operation, comprising: a semiconductor layer sequence (1) having an active region (4) suitable for generating the electromagnetic radiation, and a self-supporting and electrically conductive mechanical supporting layer (10) formed on the semiconductor layer sequence, which supporting layer mechanically supports the semiconductor layer sequence (1) and is transmissive to radiation of the semiconductor chip.

The invention relates to an optoelectronic semiconductor chip.

The document EP 0 905 797 A2 discloses radiation-emitting semiconductor chips comprising semiconductor layer sequences grown epitaxially on a growth substrate. Since the growth substrate generally absorbs part of the electromagnetic radiation generated within the layer stack, the document EP 0 905 797 A2 proposes fixing the epitaxial layer sequence to a separate carrier body with the aid of a separate connecting means and removing the growth substrate. In this case, connecting the semiconductor layer sequence to the separate carrier body by a separate connecting means and removing the growth substrate constitute relatively complicated process steps in which there is furthermore the risk of the semiconductor layer sequence being damaged.

It is an object of the present invention to specify an optoelectronic semiconductor chip which has a good radiation efficiency and which can be produced in a simple manner.

This object is achieved by means of an optoelectronic semiconductor chip comprising the features of claim 1. Advantageous developments and embodiments of the semiconductor chip are specified in subclaims 2 to 18.

An optoelectronic semiconductor chip according to the invention which emits electromagnetic radiation from its front side comprises in particular:

a semiconductor layer sequence having an active region suitable for generating the electromagnetic radiation, and

a self-supporting and electrically conductive mechanical supporting layer formed on the semiconductor layer sequence, which supporting layer mechanically supports the semiconductor layer sequence and is transmissive to the radiation of the semiconductor chip.

In contrast to the semiconductor chips in accordance with the prior art, the semiconductor chip comprising the features of claim 1 affords the advantage of dispensing with a carrier body produced apart and separately from the semiconductor layer sequence and also dispensing a growth substrate for the mechanical stabilization of the semiconductor layer sequence. Instead, a supporting layer which is electrically conductive and self-supporting, that is to say a supporting layer which is mechanically stable without further auxiliary means, is formed on the semiconductor layer sequence, said supporting layer being transmissive to the radiation of the semiconductor chip. In comparison with a separate carrier body produced separately, this supporting layer can be applied to the semiconductor layer sequence in a particularly simple manner and therefore enables a simplified production of the semiconductor chip for example in comparison with a thin-film semiconductor chip in the document EP 0 905 797 A2.

Since the supporting layer is electrically conductive, the semiconductor chip can be electrically connected via the supporting layer in a simple manner, for example with the aid of a conductive adhesive or solder.

Since the supporting layer is furthermore formed such that it is transmissive to the radiation of the semiconductor chip, it advantageously absorbs none or only a comparatively small part of the radiation generated in the semiconductor layer sequence during operation. This contributes to an increased radiation efficiency of the semiconductor chip in comparison with a semiconductor chip comprising an absorbent substrate, for example a growth substrate.

In a particularly preferred embodiment, the supporting layer is arranged on or at the rear side of the semiconductor layer sequence remote from the front side of the semiconductor chip, since the semiconductor layer sequence can then be produced in successive process steps.

However, it is also conceivable for the supporting layer to be arranged in the semiconductor layer sequence. Thus the supporting layer is arranged in a way that semiconductor layers of the semiconductor layer sequence are adjoining two sides of the supporting layer. However, the active region of the semiconductor layer sequence is preferably situated between the front side of the semiconductor chip and the supporting layer since the thickness of the material which the radiation has to penetrate through on its way to the front side of the semiconductor chip is reduced in this case.

Particularly preferably, the supporting layer has a lower refractive index than the semiconductor layer sequence. In case of doubt, the refractive index of the semiconductor layer sequence should be understood to be a value averaged over the semiconductor layer sequence.

If the active, radiation-generating region of the semiconductor layer sequence is arranged between supporting layer and front side of the semiconductor chip, this entails the advantage that a significant part of the electromagnetic radiation of the active region which impinges on a supporting layer of the semiconductor layer sequence interface is already reflected there back into the semiconductor layer sequence and does not penetrate into the supporting layer. Materials which generally have a significantly lower refractive index than the known semiconductor materials conventionally used for optoelectronic semiconductor chips are transparent conductive oxides, for example, which will be discussed in greater detail below.

In one preferred embodiment, the semiconductor layer sequence of the semiconductor chip is grown epitaxially.

The active region of the semiconductor chip preferably comprises a pn junction, a double heterostructure, a single quantum well structure or particularly preferably a multiple quantum well structure for generating radiation. In this case, the designation “quantum well structure” does not comprise any indication about the dimensionality of the quantum well structure. It therefore encompasses, inter alia, quantum wells, quantum wires and quantum dots and any combination of these structures.

The semiconductor layer sequence is based for example on a III-V compound semiconductor material such as a nitride compound semiconductor material, a phosphide compound semiconductor material or an arsenide compound semiconductor material.

In the present case, “based on nitride compound semiconductor material” means that at least one part of the semiconductor layer sequence comprises a nitride/III compound semiconductor material, preferably AlₙGaₘIn₁₋ₙ₋ₘN, where 0≦n≦1, 0≦m≦1 and n+m≦1. In this case, this material need not necessarily have a mathematically exact composition according to the above formula. Rather, it can have one or more dopants and additional constituents which essentially do not change the characteristic physical properties of the AlₙGaₘIn₁₋ₙ₋ₘN material. For the sake of simplicity, however, the above formula only comprises the essential constituents of the crystal lattice (Al, Ga, In, N), even if these can be replaced in part by small quantities of further substances.

In an equivalent manner, in the present case, “based on phosphide compound semiconductor material” means that at least one part of the semiconductor layer sequence comprises a phosphide/III compound semiconductor material, preferably AlₙGaₘI₁₋ₙ₋ₘP, where 0≦n≦1, 0≦m≦1 and n+m−1. In this case, this material, too, need not necessarily have a mathematically exact composition according to the above formula. Rather, it can have one or more dopants and additional constituents which essentially do not change the characteristic physical properties of the AlₙGaₘIn₁₋ₙ₋ₘP material. For the sake of simplicity, however, the above formula only comprises the essential constituents of the crystal lattice (Al, Ga, In, P), even if these can be replaced in part by small quantities of further substances.

Likewise in a manner equivalent to “based on nitride compound semiconductor material” and “based on phosphide compound semiconductor material”, in the present case, “based on arsenide compound semiconductor material” means that at least one part of the semiconductor layer sequence comprises an arsenide/III compound semiconductor material, preferably AlₙGaₘIn₁₋ₙ₋ₘAs, where 0≦n≦1, 0≦m≦1 and n+m≦1. This material, too, need not necessarily have a mathematically exact composition according to the above formula. Rather, it can have one or more dopants and additional constituents which essentially do not change the characteristic physical properties of the AlₙGaₘI₁₋ₙ₋ₘAs material. For the sake of simplicity, however, the above formula only comprises the essential constituents of the crystal lattice (Al, Ga, In, As), even if these can be replaced in part by small quantities of further substances.

In a particularly preferred embodiment, the supporting layer comprises a material from the group of transparent conductive oxides (TCO for short). As evidenced by the name, these oxides are electrically conductive and transmissive to electromagnetic radiation, in particular to visible light.

Transparent conductive oxides are generally metal oxides, such as, for example, zinc oxide, tin oxide, cadmium oxide, titanium oxide, indium oxide or indium tin oxide (ITO). In addition to binary metal-oxygen compounds such as, for example, ZnO, SnO₂ or In₂O₃, the group of TCOs also includes ternary metal-oxygen compounds such as, for example, Zn₂SnO₄, ZnSnO₃, MgIn₂O₄, GaInO₃, Zn₂In₂O₅ or In₄Sn₃O₁₂ or mixtures of different transparent conductive oxides. Furthermore, the TCOs do not necessarily correspond to a stoichiometric composition and can also be p- or n-doped.

In one embodiment, the supporting layer comprising a TCO is applied by a deposition or coating method, for example by means of an epitaxy process, by sputtering or a sol-gel process.

The supporting layer is preferably made no thicker than is required for reliable mechanical stability of the semiconductor chip, in order, on the one hand, to reduce the process times during the production of the semiconductor chip and, on the other hand, to be able to make the semiconductor chip as thin as possible.

Preferably, the thickness of the supporting layer is between 50 μm and 100 μm, in each case including the limits.

In one preferred embodiment, a TCO contact layer comprising a TCO is arranged between the semiconductor layer sequence and the supporting layer. In this case, the electrical contact between semiconductor layer sequence and supporting layer can be improved by in particular the supporting layer also comprising a material from the group of TCOs. An improved electrical contact between supporting layer and semiconductor layer sequence has an ohmic current-voltage characteristic, in particular. The TCO contact layer is expediently made significantly thinner than the supporting layer. Preferably, the thickness of the TCO contact layer is one to two orders of magnitude smaller than the thickness of the supporting layer and particularly preferably lies between 1 and 5 μm. For the case where both the TCO contact layer and the supporting layer comprise a TCO material, it is neither necessary for the same TCO material to be involved here nor do the TCO materials have to be able to be applied by the same method. Rather, the TCO materials can in each case be specifically adapted with regard to their desired function.

In a further particularly preferred embodiment, a reflective layer that reflects the radiation of the semiconductor chip is arranged between the active region of the semiconductor layer sequence and the rear side of the semiconductor chip, opposite the front side of said chip, and particularly preferably between semiconductor layer sequence and supporting layer. Such a reflective layer can be used to improve the reflection of electromagnetic radiation emitted from the semiconductor layer sequence in a direction of supporting layer back into the semiconductor layer sequence. The radiation efficiency of the semiconductor chip can be improved as a result.

In this case, the reflective layer can also be constructed from a plurality of layers or for example also be formed only partly over an area or in laterally structured fashion.

Particularly preferably, a distributed Bragg reflector mirror (“DBR mirror” for short) is used as the reflective layer. A DBR mirror comprises a sequence of layers whose refractive indexes are alternately high and low. A DBR mirror reflects in particular radiation that is incident perpendicular to its top side. If the supporting layer has a lower refractive index than the adjoining semiconductor layer sequence, radiation which is incident obliquely with respect to the semiconductor material/supporting layer interface, in particular, is generally reflected at said interface, while radiation which is incident perpendicular to said interface penetrates through the supporting layer and does not contribute to the radiation power of the semiconductor chip. Therefore, a DBR mirror between the active region of the semiconductor layer sequence and the supporting layer is particularly suitable for increasing the radiation efficiency of the semiconductor chip.

In addition or as an alternative to the reflective layer between the active region of the semiconductor layer sequence and the supporting layer, the rear side of the semiconductor chip preferably comprises a metal layer. The latter firstly, like the above-described reflective layer between active region of the semiconductor layer sequence and supporting layer, directs radiation to the front side of the semiconductor chip and thus increases the radiation efficiency thereof. Secondly, the metal layer generally improves the electrical contact of the rear side of the semiconductor chip to a conductive adhesive or a solder layer, which are often used in order to mount the semiconductor chip later in a housing or on a circuit board.

Furthermore, the front side of the semiconductor chip is preferably roughened. The roughening of the front side of the semiconductor chip reduces the multiple reflections of radiation at the surfaces of the semiconductor chip and therefore contributes to the improved coupling-out of radiation. Other structures are also conceivable at the front side of the semiconductor chip for coupling out radiation more efficiently, for example periodic structures which have structural elements having lateral dimensions less than or equal to the wavelength of radiation emitted by the semiconductor chip.

Preferably, the semiconductor chip comprises a current spreading layer, which is applied on that side of the semiconductor layer sequence which faces the front side of the semiconductor chip, and comprises a material from the group of TCOs. The current spreading layer advantageously has the effect that current impressed into the semiconductor chip on the front side is distributed laterally as uniformly as possible into the semiconductor layer sequence, and in particular into the active radiation-generating region thereof. This leads to an increase in the generation of radiation with energisation remaining the same, and also to a more homogenous emission characteristic of the semiconductor chip. Furthermore, a current spreading layer composed of TCO can advantageously be made significantly thinner than a current spreading layer composed of semiconductor material. Moreover, a current spreading layer composed of TCO absorbs significantly less radiation in comparison with a current spreading layer composed of a material having a higher absorption coefficient for the radiation of the semiconductor chip.

For making electrical contact with the semiconductor chip on the front side, in one preferred embodiment the front side of said semiconductor chip comprises an electrically conductive bonding pad. Via said electrically conductive bonding pad, the semiconductor chip can be electrically conductively connected, for example by means of a bonding wire, to an electrical connection of a housing or an electrical connection track of a circuit board.

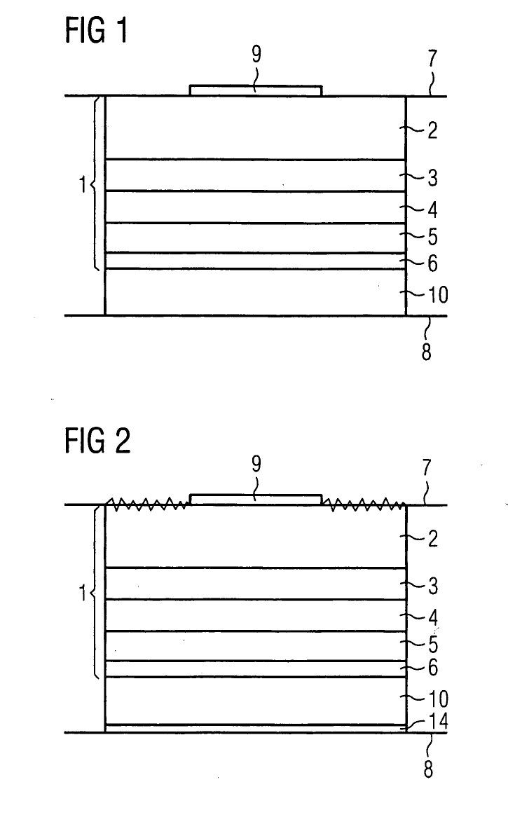

The invention is explained in more detail below on the basis of four exemplary embodiments in conjunction with FIGS. 1 to 4.

In the figures:

FIG. 1 shows a schematic sectional illustration of a semiconductor body in accordance with a first exemplary embodiment,

FIG. 2 shows a schematic sectional illustration of a semiconductor body in accordance with a second exemplary embodiment,

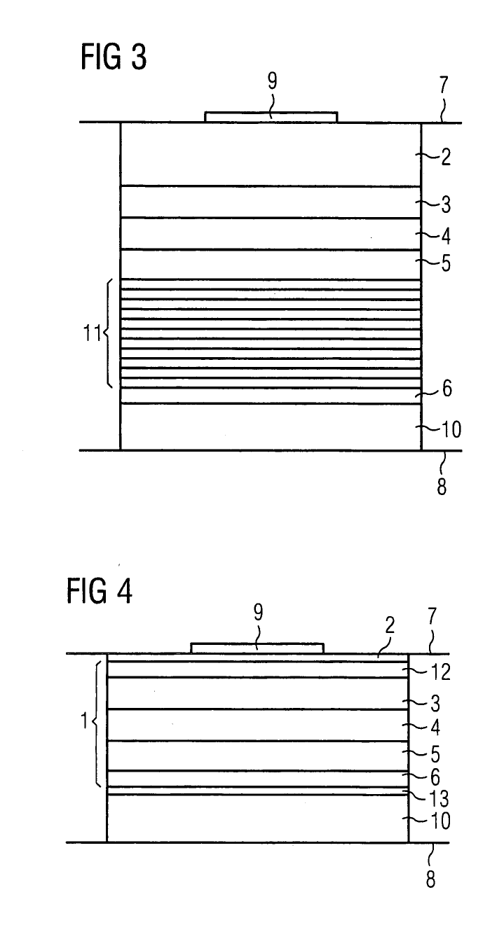

FIG. 3 shows a schematic sectional illustration of a semiconductor body in accordance with a third exemplary embodiment, and

FIG. 4 shows a schematic sectional illustration of a semiconductor body in accordance with a fourth exemplary embodiment.

In the exemplary embodiments and figures, identical or identically acting component parts are in each case provided with the same reference symbols. The elements illustrated should not in principle be regarded as true to scale, rather individual elements, such as e.g. layer thicknesses, may be illustrated with an exaggerated size in order to afford a better understanding.

In the exemplary embodiment in accordance with FIG. 1, the semiconductor chip comprises a semiconductor layer sequence 1 having a current spreading layer 2 applied on the n side, an n-type cladding layer 3, an active region 4, a p-type cladding layer 5 and a p-type contact layer 6. The active region 4 is arranged between the p-type cladding layer 5 and the n-type cladding layer 3, wherein the n-type cladding layer 3 is arranged between the active region 4 and the radiation-emitting front side 7 of the semiconductor chip and the p-type cladding layer 5 is arranged between the active region 4 and the rear side 8 of the semiconductor chip. The p-type contact layer 6 is applied to that side of the p-type cladding layer 5 which faces the rear side 8 of the semiconductor chip, while the current spreading layer 2 is disposed downstream of the n-type cladding layer 3 in the emission direction of the semiconductor chip. Furthermore, a front-side electrical bonding pad 9 is applied to the current spreading layer 2, from which bonding pad for example contact fingers extend laterally over the front side 7 of the semiconductor chip (not illustrated in the figure) and to which bonding pad 9 it is possible to apply a bonding wire for electrically contact-connecting the semiconductor chip to an electrically conductive region of a housing or a circuit board. Furthermore, a supporting layer 10 is formed onto that side of the p-type contact layer 6 which faces the rear side 8 of the semiconductor chip, said supporting layer 10 being electrically conductive and transmissive to radiation of the semiconductor chip.

As an alternative, the semiconductor chip can also be provided for being electrically connected on the front side while dispensing with a bonding wire, for example by means of an electrically conductive layer that electrically conductively connects the front side 7 of the semiconductor chip to an electrically conductive region of a housing or a circuit board.

In the present case, the semiconductor layer sequence 1 is based on a phosphide compound semiconductor material. In the present case, the active region 4 comprises for example undoped InGaAlP, has a thickness of between 100 nm and 1 μm and generates electromagnetic radiation from the yellow to red spectral range of visible light during operation. The n-type cladding layer 3 comprises n-doped InAlP and the p-type cladding layer 5 comprises p-doped InAlP. The cladding layers 3, 5 each have a thickness of between 200 nm and 1 μm. The p-type contact layer 6 comprises highly p-doped AlGaAs and has a thickness of between 50 nm and 200 nm. The current spreading layer 2 comprises InGaAlP or AlGaAs and preferably has a thickness of between 1 μm and 10 μm.

As already mentioned in the general part of the description, the active region 4 for generating radiation comprises for example a pn junction, a double heterostructure, a single quantum well or a multiple quantum well structure. The n-type cladding layer 3 and the p-type cladding layer 5 have the task of circumscribing the respective charge carriers to the active region 4. The p-type contact layer 6 furthermore serves for producing an improved electrical contact, preferably with an ohmic current-voltage characteristic, to the supporting layer 10, while with the aid of the current spreading layer 2 current impressed into the semiconductor chip via the front-side bonding pad 9 is distributed laterally as uniformly as possible into the semiconductor layer sequence 1 and in particular into the active radiation-generating region 4.

In the present case, the semiconductor layer sequence 1 is grown epitaxially for example on a GaAs growth substrate. The supporting layer 10 is subsequently applied to that side of the p-type contact layer 6 which faces the rear side 8 of the semiconductor chip, for example by means of a deposition or coating method. Said supporting layer comprises a TCO, in the present case aluminum-doped zinc oxide ZnO:Al (2%). The supporting layer 10 can be applied epitaxially, by means of sputtering, or with the aid of a sol-gel process. Sol-gel processes for applying TCO layers are described for example in the documents DE 197 19 162 A1 and L. Spanhel et al., “Semiconductor Clusters in Sol-Gel Process: Quantized Aggregation, Gelation and Crystal Growth in Concentrated ZnO Colloids”, J. Am. Chem. Soc. (1991), 113, 2826-2833, the disclosure contents of which in this regard are in each case incorporated by reference.

In the exemplary embodiment in accordance with FIG. 1, the thickness of the supporting layer 10 is between 50 μm and 100 μm and stabilizes the semiconductor chip mechanically to a sufficient extent, such that the growth substrate can be removed after the supporting layer 10 has been applied. The growth substrate is removed for example by grinding and/or selective wet-chemical etching.

On account of the difference between the refractive index of the semiconductor layer sequence 1 (n(InGaAlP)≈3.5) and the refractive index of the supporting layer 10 (n(ZnO)≈1.85), in the case of the semiconductor chip in FIG. 1, radiation which is generated in the active region 4 of the semiconductor layer sequence 1 and impinges on the semiconductor layer sequence 1/supporting layer 10 interface is reflected back into the semiconductor layer sequence 1.

In contrast to the semiconductor chip in accordance with the exemplary embodiment of FIG. 1, the semiconductor chip in the exemplary embodiment in accordance with FIG. 2 comprises a roughened front side 7, which can be produced by etching, for example.

The roughening of the front side of the semiconductor chip 7 enables the radiation to be coupled out better from the semiconductor chip into the surroundings, since radiation losses on account of multiple reflection at the interfaces of semiconductor body/surroundings are generally reduced.

Furthermore, the rear side 8 of the semiconductor chip in FIG. 2 comprises a metal layer 14, which is provided for improving the electrical contact with a conductive adhesive or solder by means of which the semiconductor chip is mounted in a housing or on a circuit board at a later point in time. Furthermore, the metal layer 14 reflects radiation generated within the semiconductor layer sequence 1 back into the latter. The metal layer 14 has for example gold or aluminum.

In contrast to the exemplary embodiments in accordance with FIG. 1 and FIG. 2, the semiconductor chip of the exemplary embodiment in accordance with FIG. 3 comprises a reflective layer, in the present case a DBR mirror 11 arranged between the p-type cladding layer 5 and the p-type contact layer 6. The DBR mirror 11 has a sequence of layers, in the present case between ten and twenty, which alternately have a high refractive index and a low refractive index. In the present exemplary embodiment, the DBR mirror for reflecting the radiation from the yellow to red spectral range of visible light can be based for example on AlGaAs or AlGaInP, the refractive indexes being varied alternately in each case by variation of the Al and/or Ga content of the layers.

In the exemplary embodiment in accordance with FIG. 4, in contrast to the exemplary embodiment in accordance with FIG. 1, the semiconductor chip comprises an n-type contact layer 12 composed of highly n-doped AlGaAs having a thickness of between 50 and 200 nm, which is arranged on that side of the n-type cladding layer 3 which faces the front side 7 of the semiconductor chip. An n-side current spreading layer 2 comprising a TCO and having a thickness of between 200 nm and 1 μm is disposed downstream of the n-type contact layer 12 as seen from the semiconductor layer sequence 1. In order to improve the electrical contact between the n-type contact layer 12 and the n-side current spreading layer 2 composed of TCO, preferably in such a way that it has an ohmic current-voltage characteristic, it is possible to arrange between these two layers contact locations for example composed of AuGe (not illustrated in the figure).

In the exemplary embodiment in accordance with FIG. 4, a TCO contact layer 13 comprising a TCO is arranged between the p-type contact layer 6 and the TCO supporting layer 10. In this case, the TCO contact layer 13 does not necessarily have the same material as the supporting layer 10 and contributes to an improved electrical contact with preferably an ohmic current-voltage characteristic between the supporting layer 10 and the semiconductor layer sequence 1. For the sake of completeness, it should be pointed out that such a TCO contact layer 13 can also be present in the three exemplary embodiments described above.

This patent application claims the priority of German patent application 102005047168.4, the disclosure content of which is hereby incorporated by reference.

The invention is not restricted by the description on the basis of the exemplary embodiments. Rather, the invention encompasses any new feature and any combination of features, which in particular comprises any combination of features in the patent claims, even if this feature or this combination itself is not explicitly specified in the patent claims or exemplary embodiments.

1. An optoelectronic semiconductor chip which emits electromagnetic radiation from its front side during operation, comprising:
a semiconductor layer sequence having an active region suitable for generating the electromagnetic radiations; and
a self-supporting and electrically conductive mechanical supporting layer formed on the semiconductor layer sequence, which supporting layer mechanically supports the semiconductor layer sequence and is transmissive to radiation of the semiconductor chip.

2. The optoelectronic semiconductor chip as claimed in claim 1, in which the supporting layer is arranged on that side of the semiconductor layer sequence which is remote from the front side of the semiconductor chip.

3. The optoelectronic semiconductor chip as claimed in claim 1, in which the active region is arranged between supporting layer and front side of the semiconductor chip.

4. The optoelectronic semiconductor chip as claimed in claim 1, in which the supporting substrate has a refractive index which is less than the refractive index of the semiconductor layer sequence.

5. The optoelectronic semiconductor chip as claimed in claim 1, in which the semiconductor layer sequence is grown epitaxially.

6. The optoelectronic semiconductor chip as claimed in claim 1, in which the supporting layer is formed by a deposition method or a coating method.

7. The optoelectronic semiconductor chip as claimed in claim 1, in which the supporting layer comprises a material from the group of transparent conductive oxides (TCOs).

8. The optoelectronic semiconductor chip as claimed in claim 6, in which the supporting layer is applied epitaxially by means of sputtering or with the aid of a sol-gel process.

9. The optoelectronic semiconductor chip as claimed in claim 1, in which the supporting layer has a thickness of ≧50 μm and ≦100 μm.

10. The optoelectronic semiconductor chip as claimed in claim 1, in which a TCO contact layer is arranged between the semiconductor layer sequence and the supporting layer, said TCO contact layer producing an electrical contact between the semiconductor layer sequence and the supporting layer (10) and having a material from the group of transparent conductive oxides (TCOs).

11. The optoelectronic semiconductor chip as claimed in claim 10, in which the TCO contact layer has a thickness which is one to two orders of magnitude smaller than the thickness of the supporting layer.

12. The optoelectronic semiconductor chip as claimed in claim 10, in which the TCO contact layer has a thickness which is ≧1 μm and ≦5 μm.

13. The optoelectronic semiconductor chip as claimed in claim 1, in which a layer that reflects the radiation of the semiconductor chip is arranged between the active region of the semiconductor layer sequence and the supporting layer.

14. The optoelectronic semiconductor chip as claimed in claim 13, in which the reflective layer is a DBR mirror (distributed Bragg reflector mirror).

15. The optoelectronic semiconductor chip as claimed in claim 1, in which a rear side of the semiconductor chip, arranged opposite the front side of said chip, comprises a metal layer.

16. The optoelectronic semiconductor chip as claimed in claim 15, in which the metal layer is formed in reflective fashion for the radiation of the semiconductor chip.

17. The optoelectronic semiconductor chip as claimed in claim 1, the front side of which is roughened.

18. The optoelectronic semiconductor chip as claimed in claim 1, in which a current spreading layer having a material from the group of transparent conductive oxides (TCO) is arranged on that side of the semiconductor layer sequence which faces the front side of said chip.
